(19) United States
(12) Patent Application Publication
(10) Pub. No.: US 2024/0353443 A1
(43) Pub. Date: Oct. 24, 2024

(54) Probe Structure and Electronic Device with Probe Structure

(71) Applicants: Gree Electric Appliances, Inc. of Zhuhai, Zhuhai, Guangdong (CN); Leayun Technology Co., Ltd. of Zhuhai, Zhuhai, Guangdong (CN)

(72) Inventors: Xing LIU, Zhuhai, Guangdong (CN); Yang GE, Zhuhai, Guangdong (CN); Anfu ZENG, Zhuhai, Guangdong (CN); Changfeng LIU, Zhuhai, Guangdong (CN); Xiaojian LI, Zhuhai, Guangdong (CN)

(21) Appl. No.: 18/689,357

(22) PCT Filed: Sep. 23, 2022
(86) PCT No.: PCT/CN2022/121041

§ 371 Date: Mar. 5, 2024

(30) Foreign Application Priority Data
Oct. 25, 2021 (CN) 202111242439.1

(51) Int. Cl. G01R 1/067

(52) U.S. Cl. CPC G01R 1/06716

(57) ABSTRACT

Some embodiments of the present disclosure provide a probe structure and an electronic device with probe structure. The probe structure is disposed on a first component and is configured to contact with a conductive component on a second component, the probe structure includes a probe assembly, the probe assembly includes a storage position and a contact position, when the probe assembly is at the storage position, the probe assembly is stored in the first component so as to avoid being damaged by an external force, and when the probe assembly is at the contact position, at least part of the probe assembly extends out of the first component so as to contact with the conductive component; the probe assembly is movably disposed to move between the storage position and the contact position.

### CROSS-REFERENCE TO RELATED DISCLOSURE

The present disclosure claims the priority to Chinese Patent Disclosure No.202111242439.1, filed on Oct. 25, 2021, and entitled “Probe Structure and Electronic Device Having Same”. The contents of which are hereby incorporated by reference in its entirety.

### TECHNICAL FIELD

The present disclosure relates to a technical field of electric connections, and in particular to a probe structure and an electronic device with probe structure.

### BACKGROUND

Miniaturized electronic products, such as wearable devices, which have the characteristics of small volumes and light weights, and thus are prone to problems of insufficient structural spaces, damage to design appearances and the like, if traditional USB series interfaces are used for charging and data transmission.

At present, in precise connections of the miniaturized electronic products with TWS earphones, and bracelet-type and ring-type wearable devices as representatives, the use of a probe structure is a new effective solution, which is specifically a connection mode of a combination of “a metal contact on a product body and a probe structure of a charging base”. In this way, while it is ensured that the appearance is close to an ID, the combination also has the advantages of small space occupancy, large charging current, etc.

However, due to the limitation of its own structure, the probe structure can only be subjected to an acting force in an up-and-down direction to perform axial extension and retraction, and thus the ranges of the direction and angle of the force that the probe structure can withstand is very small. In the prior art, the probe structure is embedded into a plastic housing by means of an injection molding process, a probe assembly of the probe structure is exposed outside the housing, the part exposed outside the housing is prone to external acting forces in various directions, and the acting forces in these directions, especially in a tangential direction, are extremely prone to colliding with a precise internal structure of the probe structure, resulting in a phenomenon of poor contact between the probe structure and the contact, such that functional failures occur in parts and components, and a system cannot normally operate at last.

### SUMMARY

Some embodiments of the present disclosure provide a probe structure and an electronic device with probe structure, so as to solve the problem of a probe assembly of a probe structure in an art known to inventors being prone to an external acting force to damage an internal structure.

In order to achieve the above objective, according to one aspect of some embodiments of the disclosure, provided is a probe structure, which is disposed on a first component so as to contact with a conductive component on a second component, the probe structure includes a probe assembly, the probe assembly includes a storage position at which the probe assembly is stored in the first component so as to avoid being damaged by an external force, and a contact position at which the probe assembly at least part of the probe assembly extends out of the first component so as to contact with the conductive component; the probe assembly is movably disposed to move between the storage position and the contact position.

In some embodiments, the probe structure includes a driving assembly, which is movably disposed on the first component, and the driving assembly is connected with the probe assembly, so as to drive the probe assembly to move between the storage position and the contact position.

In some embodiments, the first component includes a housing, and an avoidance groove is disposed on an outer surface of the housing, when the probe assembly is at the storage position, the probe assembly is stored in the avoidance groove; or, an accommodating cavity which communicates with the avoidance groove for accommodating the driving assembly is disposed on the housing, and when the probe assembly is at the storage position, the probe assembly is stored in the accommodating cavity after passing through the avoidance groove; or, an accommodating cavity which communicates with the avoidance groove for accommodating the driving assembly is disposed on the housing, and when the probe assembly is at the storage position, a part of the probe assembly is stored in the avoidance groove, and the other part of the probe assembly is stored in the accommodating cavity.

In some embodiments, the probe assembly includes a rotating portion and a needle body, the rotating portion is rotatably disposed on the avoidance groove, one end of the needle body is connected with the rotating portion, and the other end of the needle body extends in a direction away from the rotating portion; the needle body retracts into the first component or extends out of the first component by means of the rotation of the rotating portion.

In some embodiments, an insertion protrusion is disposed on one of the avoidance groove and the rotating portion, an insertion groove is disposed on the other one of the avoidance groove and the rotating portion; the insertion protrusion is inserted into the insertion groove and is in clearance fit with the insertion groove, and the rotating portion rotates relative to the avoidance groove.

In some embodiments, at least part of the driving assembly is disposed on the accommodating cavity, and the driving assembly includes: a first transmission member, rotatably disposed on the first component; and a second transmission member, a first end of the second transmission member is slidably and rotatably connected with the first transmission member, and a second end of the second transmission member is hinged with the probe assembly; the second transmission member drives the probe assembly to move by means of the rotation of the first transmission member.

In some embodiments, the first transmission member includes: a driving portion, a first end of the driving portion is located outside the housing, a second end of the driving portion is located in the accommodating cavity; the second end of the driving portion is rotatably connected with the housing, and the second end of the driving portion rotates by means of driving the first end of the driving portion to move; and a transmission portion, wherein the transmission portion is located in the accommodating cavity, a first end of the transmission portion is connected with the second end of the driving portion, a groove is disposed on a second end of the transmission portion, and the first end of the second transmission member is rotatably and is slidably disposed in the groove.

In some embodiments, at least part of the driving portion is a strip-shaped rod body, and the center line of the strip-shaped rod body and the rotation axis of the driving portion are disposed at a predetermined angle; the transmission portion includes a first rod body and a second rod body, which are connected with each other, an end of the first rod body which is away from the second rod body is connected with a second end of the strip-shaped rod body, and an end of the second rod body which is away from the first rod body is connected with the second transmission member; and the center lines of any two of the strip-shaped rod body, the first rod body and the second rod body are disposed at a predetermined angle, so as to jointly form the first transmission member.

In some embodiments, the driving portion includes a strip-shaped rod body and a protrusion portion which is located at the first end of the strip-shaped rod body, at least part of the strip-shaped rod body is located in the accommodating cavity; a mounting groove for accommodating the second component is disposed on the first component, an opening portion corresponding to the protrusion portion is disposed on a groove wall surface of the mounting groove, and the protrusion portion is movably disposed at the opening portion; and the protrusion portion includes an initial position at which the protrusion portion at least partially protrudes out of the opening portion to be located in the mounting groove so as to contact with the opening portion, and an avoidance position at which the protrusion portion is completely located in the opening portion to avoid the second component, and the protrusion portion is movably disposed between the initial position and the avoidance position.

In some embodiments, the driving assembly includes an elastic reset member, the elastic reset member is located between a side of the strip-shaped rod body which is away from the protrusion portion and the housing; the protrusion portion reaches the avoidance position from the initial position under the propulsion of the second component, so as to compress the elastic reset member; or, the protrusion portion returns from the avoidance position to the initial position under the action of an elastic force of the elastic reset member.

In some embodiments, the driving portion includes a strip-shaped rod body and a rotary connecting portion which is located at a second end of the strip-shaped rod body, a shaft body is disposed on one of the rotary connecting portion and the housing, a shaft hole is disposed on the other one of the rotary connecting portion and the housing; the shaft body is inserted into the shaft hole, and the driving portion rotates relative to the housing.

In some embodiments, the probe assembly includes a rotating portion and a needle body, the rotating portion is rotatably disposed in the avoidance groove, and the needle body is connected with the rotating portion so as to rotate along with the rotating portion; and the second transmission member includes a connecting rod, a first connecting shaft and a second connecting shaft, the first connecting shaft and the second connecting shaft are respectively disposed at two ends of the connecting rod, the center lines of the first connecting shaft and the second connecting shaft are parallel to each other and are perpendicular to the center line of the connecting rod, the first connecting shaft is used for being connected with the first transmission member, and the second connecting shaft is used for being hinged with the rotating portion, so as to drive the rotating portion to rotate.

In some embodiments, the probe assembly includes a needle rod and a needle cylinder, the needle cylinder is located in the accommodating cavity, and at least part of the needle rod is telescopically disposed in the needle cylinder, so as to extend out of the needle cylinder to contact with the conductive component or retract into the needle cylinder to avoid being damaged.

In some embodiments, the driving assembly includes: an armature, disposed at an end of the needle rod close to the bottom of the needle cylinder and is fixedly connected with the needle rod; a coil and iron core assembly, disposed at the bottom of the needle cylinder; and an elastic connecting member, located between the armature and the coil and iron core assembly, so as to connect the armature with the coil and iron core assembly.

In some embodiments, the driving assembly includes: a detection component, being used for detecting whether the second component reaches a predetermined position on the first component, and transmitting a detection signal to a controller; and a motor, an output shaft of the motor is connected with the probe assembly, and the motor is electrically connected with the controller; the controller receives the detection signal, and sends a driving instruction to the motor so as to control the motor to drive the probe assembly to move.

According to another aspect of the disclosure, provided is an electronic device, including a wearable device and a base, the base is for charging the wearable device or performing data transmission with the wearable device or charging the wearable device and performing data transmission with the wearable device, the electronic device further includes: a probe structure mentioned above, the wearable device is electrically connected with the base by means of the probe structure; and one of the wearable device and the base is a first component, and the other one of the wearable device and the base is a second component.

By means of applying the technical solution of the disclosure, the probe structure of the disclosure is disposed on the first component for contacting with the conductive component on the second component, so as to form an electrical connection between the first component and the second component, the probe structure includes the probe assembly, the probe assembly includes a storage position at which the probe assembly is stored in the first component so as to avoid being damaged by the external force, and the contact position at which the probe assembly at least part of the probe assembly extends out of the first component so as to contact with the conductive component, and the probe assembly is movably disposed to move between the storage position and the contact position. In this way, when the second component needs to be electrically connected with the first component, the needle body of the probe assembly can extend out of the first component, so as to contact with the conductive component of the second component; and when the second component does not need to be electrically connected with the first component, the needle body of the probe assembly can be stored back in the first component and no longer protrudes out or exceeds the outer surface of the first component, so as to avoid a fault or failure caused by an internal collision resulting from an external acting force, thereby solving the problem of a probe assembly of a probe structure in an art known to inventors being prone to an external acting force to damage an internal structure.

### BRIEF DESCRIPTION OF THE DRAWINGS

The drawings of the description forming a part of the disclosure are used to provide a further understanding of the disclosure, and the schematic embodiments of the disclosure and the description thereof are used to explain the disclosure, and do not constitute an improper limitation on the disclosure. In the drawings:

FIG. 1 illustrates a schematic structural diagram of an embodiment of a first component provided by some embodiments of the disclosure;

FIG. 2 illustrates a semi-sectional view of the first component shown in FIG. 1;

FIG. 3 illustrates a schematic structural diagram of an embodiment of a second component provided by some embodiments of the disclosure; and

FIG. 4 illustrates a schematic structural diagram of an embodiment of a probe structure provided by some embodiments of the disclosure.

The above drawings include the following reference signs:

1, first component; 10, housing; 11, accommodating cavity; 12, avoidance groove; 13, mounting groove; 14, opening portion;

2, second component; 20, body; 21, conductive component;

3, probe assembly; 31, rotating portion; 32, needle body; 33, wire;

4, driving assembly; 41, first transmission member; 411, driving portion; 4111, strip-shaped rod body; 4112, protrusion portion; 4113, rotary connecting portion; 412, transmission portion; 4121, first rod body; 4122, second rod body; 413, groove; 42, second transmission member; 421, connecting rod; 422, first connecting shaft; 423, second connecting shaft; 43, first guide pillar.

### DETAILED DESCRIPTION OF THE EMBODIMENTS

It should be noted that, if there is no conflict, embodiments in the disclosure and features in the embodiments can be combined with each other. Hereinafter, the disclosure will be described in detail with reference to the drawings and in conjunction with the embodiments.

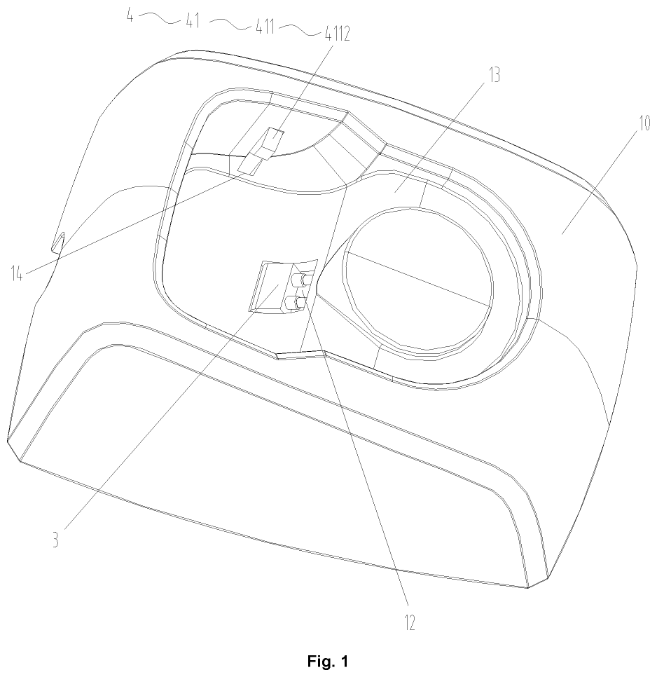

As shown in FIG. 1 to FIG. 4, the embodiment of the disclosure provides a probe structure, which is disposed on a first component 1 so as to contact with a conductive component 21 on a second component 2, and the probe structure includes a probe assembly 3, the probe assembly 3 includes a storage position at which the probe assembly is stored in the first component 1 so as to avoid being damaged by an external force, and a contact position at which the probe assembly at least part of the probe assembly 3 extends out of the first component 1 so as to contact with the conductive component 21, and the probe assembly 3 is movably disposed to move between the storage position and the contact position.

The probe structure of the disclosure is disposed on the first component 1 for contacting with the conductive component 21 on the second component 2, so as to form an electrical connection between the first component 1 and the second component 2, the probe structure includes the probe assembly 3, the probe assembly 3 includes the storage position at which the probe assembly is stored in the first component 1 so as to avoid being damaged by the external force, and the contact position at which the probe assembly at least partially extends out of the first component 1 so as to contact with the conductive component 21, and the probe assembly 3 is movably disposed to move between the storage position and the contact position. In this way, when the second component 2 needs to be electrically connected with the first component 1, a needle body of the probe assembly 3 can extend out of the first component 1, so as to contact with the conductive component 21 of the second component 2; and when the second component 2 does not need to be electrically connected with the first component 1, the needle body of the probe assembly 3 can be stored back in the first component 1 and no longer protrudes out or exceeds an outer surface of the first component 1, so as to avoid a fault or failure caused by an internal collision resulting from an external acting force, thereby solving the problem of a probe assembly of a probe structure in a art known to inventors being prone to an external acting force to damage an internal structure.

In some embodiments, the probe structure of the disclosure includes a driving assembly 4, the driving assembly 4 is movably disposed on the first component 1, and the driving assembly 4 is connected with the probe assembly 3 in a driving manner, so as to drive the probe assembly 3 to move between the storage position and the contact position.

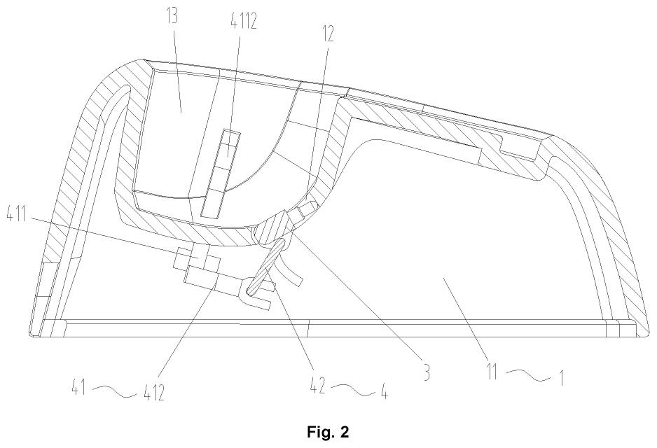

As shown in FIG. 1 and FIG. 2, the first component 1 includes a housing 10, and an outer surface of the housing 10 is provided with an avoidance groove 12, wherein when the probe assembly 3 is at the storage position, the probe assembly 3 is stored in the avoidance groove 12; or, the housing 10 is internally provided with an accommodating cavity 11 which communicates with the avoidance groove 12 for accommodating the driving assembly 4, and when the probe assembly 3 is at the storage position, the probe assembly 3 is stored in the accommodating cavity 11 after passing through the avoidance groove 12; or, the housing 10 is internally provided with an accommodating cavity 11 which communicates with the avoidance groove for accommodating the driving assembly 4, and when the probe assembly 3 is at the storage position, a part of the probe assembly 3 is stored in the avoidance groove 12, and the other part of the probe assembly 3 is stored in the accommodating cavity 11.

In some embodiments, the housing 10 of the first component 1 can be formed by injection molding, and the probe assembly 3 can be installed on the housing 10 by using an in-mold insert, such that the dustproof and waterproof performance of an electronic device having the probe structure of the disclosure can be greatly improved, thereby improving the usage experience of a user, so as to reduce after-sales and maintenance costs.

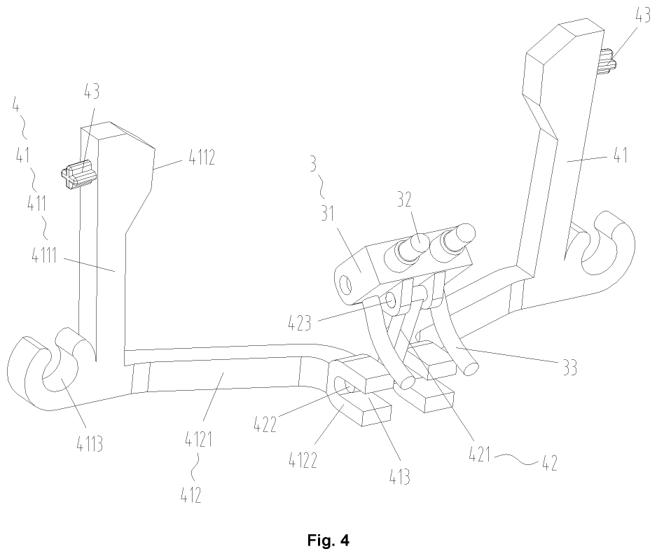

As shown in FIG. 1 and FIG. 4, the probe assembly 3 includes a rotating portion 31 and a needle body 32, the rotating portion 31 is rotatably disposed in the avoidance groove 12, one end of the needle body 32 is connected with the rotating portion 31, and the other end of the needle body 32 extends in a direction away from the rotating portion 31, so as to retract into the first component 1 or extend out of the first component 1 by means of the rotation of the rotating portion 31.

In some embodiments,, one of the avoidance groove 12 and the rotating portion 31 is provided with an insertion protrusion, the other one of the avoidance groove 12 and the rotating portion 31 is provided with an insertion groove, and the insertion protrusion is inserted into the insertion groove and is in clearance fit with the insertion groove, so that the rotating portion 31 rotates relative to the avoidance groove 12.

As shown in FIG. 2, at least part of the driving assembly 4 is located in the accommodating cavity 11, and the driving assembly 4 includes: a first transmission member 41, which is rotatably disposed on the first component 1; and a second transmission member 42, a first end of which is slidably and rotatably connected with the first transmission member 41, and a second end of which is hinged with the probe assembly 3, so that the second transmission member 42 drives the probe assembly 3 to move by means of the rotation of the first transmission member 41.

As shown in FIG. 4, the first transmission member 41 includes a driving portion 411, a first end of the driving portion 411 is located outside the housing 10, a second end of the driving portion 411 is located in the accommodating cavity 11, and the second end of the driving portion 411 is rotatably connected with the housing 10, so as to drive the second end of the driving portion 411 to rotate by means of driving the first end of the driving portion 411 to move; and a transmission portion 412, wherein the transmission portion 412 is located in the accommodating cavity 11, a first end of the transmission portion 412 is connected with the second end of the driving portion 411, a second end of the transmission portion 412 is provided with a groove 413, and the first end of the second transmission member 42 is rotatably and is slidably disposed in the groove 413.

In some embodiments, at least part of the driving portion 411 is a strip-shaped rod body 4111, and the center line (i.e., the extension line) of the strip-shaped rod body 4111 and the rotation axis of the driving portion 411 are disposed to form a certain included angle; the transmission portion 412 includes a first rod body 4121 and a second rod body 4122, which are connected with each other, the end of the first rod body 4121 that is away from the second rod body 4122 is connected with a second end of the strip-shaped rod body 4111, and the end of the second rod body 4122 that is away from the first rod body 4121 is connected with the second transmission member 42; and the center lines (i.e., the extension lines) of any two of the strip-shaped rod body 4111, the first rod body 4121 and the second rod body 4122 are disposed to form a certain included angle, so as to jointly form the first transmission member 41.

In some embodiments, the center line (i.e., the extension line) of the strip-shaped rod body 4111 and the rotation axis of the driving portion 411 are perpendicular to each other, the included angle between the center line of the strip-shaped rod body 4111 and the center line of the first rod body 4121 is an obtuse angle, the included angle between the center line of the first rod body 4121 and the center line of the second rod body 4122 is an obtuse angle, the center line of the strip-shaped rod body 4111 and the center line of the second rod body 4122 are perpendicular to each other, and the rotation axis of the driving portion 411 and the center line of the second rod body 4122 are parallel to each other.

As shown in FIG. 1, FIG. 2 and FIG. 4, the driving portion 411 includes a strip-shaped rod body 4111 and a protrusion portion 4112 located at the first end of the strip-shaped rod body 4111, at least part of the strip-shaped rod body 4111 is located in the accommodating cavity 11; the first component 1 is provided with a mounting groove 13 for accommodating the second component 2, a groove wall surface of the mounting groove 13 is provided with an opening portion 14 corresponding to the protrusion portion 4112, and the protrusion portion 4112 is movably disposed at the opening portion 14; and the protrusion portion 4112 has an initial position at which the protrusion portion at least partially protrudes out of the opening portion 14 to be located in the mounting groove 13 so as to contact with the opening portion 14, and an avoidance position at which the protrusion portion is completely located in the opening portion 14 to avoid the second component 2, and the protrusion portion 4112 is movably disposed between the initial position and the avoidance position.

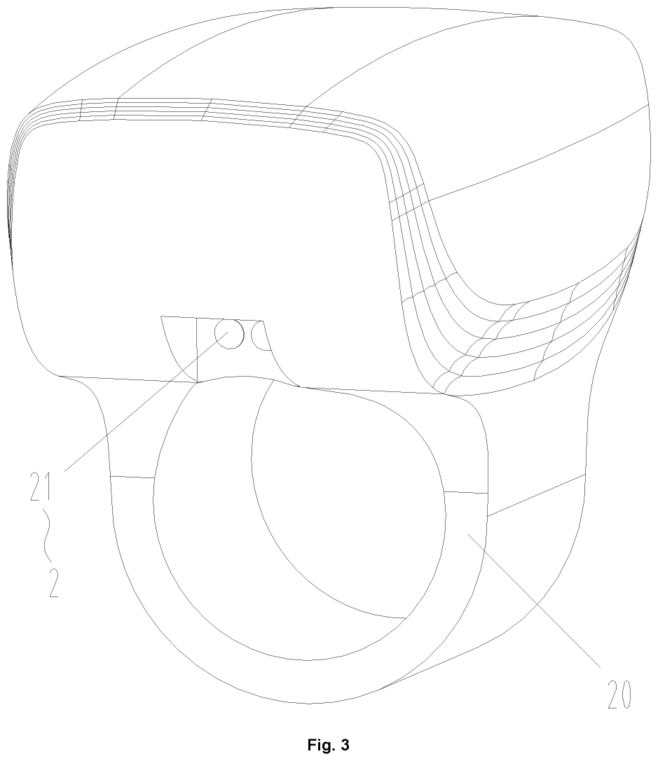

As shown in FIG. 3, the second component 2 includes a body 20 and a conductive component 21 disposed on the body 20, and the mounting groove 13 is of a groove body structure, which is adapted to the shape of the body 20 for inserting the body 20 therein.

In some embodiments, since the main function of using the probe structure is to implement power transmission or data transmission between the first component 1 and the second component 2 after forming butt-joint with the conductive component 21, and the condition for judging whether it is necessary to transmit power or data is that whether the second component 2 is placed in the mounting groove 13, the driving assembly 4 is disposed on the first component 1, the extension or retraction of the probe assembly 3 is implemented by means of the motion of the driving assembly 4 when separating from or contacting with the second component 2, and thus it is possible to simultaneously ensure good contact at work and collision protection during idle times.

As shown in FIG. 4, the driving assembly 4 further includes an elastic reset member, which is located between the side of the strip-shaped rod body 4111 that is away from the protrusion portion 4112 and the housing 10; the protrusion portion 4112 reaches the avoidance position from the initial position under the propulsion of the second component 2, so as to compress the elastic reset member; or, the protrusion portion 4112 returns from the avoidance position to the initial position under the action of an elastic force of the elastic reset member.

In some embodiments, the elastic reset member is a compression spring, the side of the strip-shaped rod body 4111 that is away from the protrusion portion 4112 is provided with a first guide pillar 43, the housing 10 is also provided with a second guide pillar, and two ends of the compression spring are respectively sheathed on the first guide pillar 43 and the second guide pillar, so as to be installed between the strip-shaped rod body 4111 and the housing 10.

In this way, by means of the structures such as the protrusion portion 4112 and the elastic reset member, which are disposed on a butt-joint path of the first component 1 and the second component 2, the working state of the probe structure is judged, and then the posture of the probe assembly 3 in the working/idle state is adjusted by means of the action of the driving portion 411, so as to achieve the function of storing the probe assembly 3 in the idle state to avoid accidental collision and extending out the probe assembly 3 in the working state to recover a pairing posture.

In some embodiments, the driving portion 411 includes a strip-shaped rod body 4111 and a rotary connecting portion 4113 located at the second end of the strip-shaped rod body 4111, one of the rotary connecting portion 4113 and the housing 10 is provided with a shaft body, the other one of the rotary connecting portion 4113 and the housing 10 is provided with a shaft hole, and the shaft body is inserted into the shaft hole, so that the driving portion 411 rotates relative to the housing 10. The rotary connecting portion 4113 is located on the side of the strip-shaped rod body 4111 that is away from the transmission portion 412.

As shown in FIG. 4, the probe assembly 3 includes a rotating portion 31 rotatably disposed in the avoidance groove 12, and a needle body 32 connected with the rotating portion 31 so as to rotate along with the rotating portion 31; and the second transmission member 42 includes a connecting rod 421, and a first connecting shaft 422 and a second connecting shaft 423 which are respectively disposed at two ends of the connecting rod 421, the center lines of the first connecting shaft 422 and the second connecting shaft 423 are parallel to each other and are perpendicular to the center line of the connecting rod 421, the first connecting shaft 422 is used for being connected with the first transmission member 41, and the second connecting shaft 423 is used for being hinged with the rotating portion 31, so as to drive the rotating portion 31 to rotate.

In some embodiments, a wire 33 of the probe assembly 3 is connected with a PCB of the first component 1 by means of a needle file or in a welding manner, and the PCB of the first component 1 can implement functions, such as power supply and data transmission, with an external device by means of a universal interface such as a Type-C Micro-USB.

The specific action modes of the probe structure of the disclosure are as follows:

(1) When the second component 2 is placed in the mounting groove 13, the second component 2 extrudes the protrusion portion 4112 in a direction close to the interior of the housing 10, and the protrusion portion 4112 drives the strip-shaped rod body 4111 to rotate around the shaft body that is connected with the rotary connecting portion 4113, so that a groove 413 in the end of the transmission portion 412 that is away from the connecting portion 4113 moves upwards to drive the first connecting shaft 422 in the groove 413 to rotate and slide, and thus the connecting rod 421 and the second connecting shaft 423 move accordingly to drive the rotating portion 31 to rotate around the insertion protrusion, thereby realizing the rotary extension of the needle body 32 and completing the posture adjustment of the probe assembly 3.

(2) After the second component 2 is completely placed in the mounting groove 13, the conductive component 21 is in contact with the needle body 32 to realize the butt-joint of interfaces, so as to perform power transmission or data transmission.

(3) When the second component 2 is taken out, under the action of the elastic reset member, the strip-shaped rod body 4111 rotates reversely around the shaft body that is connected with the rotary connecting portion 4113, so that the protrusion portion 4112 returns to the initial position and drives the rotating portion 31 to return to the storage position, therefore the rotating portion 31 is stored in the housing 10 to protect the probe assembly 3.

In one unshown embodiment of the disclosure, the probe assembly 3 includes a needle rod and a needle cylinder, the needle cylinder is located in the accommodating cavity, and at least part of the needle rod is telescopically disposed in the needle cylinder, so as to extend out of the needle cylinder to contact with the conductive component 21 or to retract into the needle cylinder to avoid being damaged.

In some embodiments, the driving assembly 4 includes: an armature, which is disposed at the end of the needle rod close to the bottom of the needle cylinder and is fixedly connected with the needle rod; a coil and iron core assembly, which is disposed at the bottom of the needle cylinder; and an elastic connecting member, which is located between the armature and the coil and iron core assembly, so as to connect the armature with the coil and iron core assembly. By means of electrifying a coil, the armature and the needle rod are sucked back into the needle cylinder to avoid damage, or by means of de-electrifying the coil, the elastic force of the elastic connecting member pushes the needle rod back to a position in contact with the conductive component 21.

In another unshown embodiment of the disclosure, the driving assembly 4 includes: a detection component, which is used for detecting whether the second component 2 reaches a predetermined position on the first component 1, and transmitting a detection signal to a controller; and a motor, wherein an output shaft of the motor is connected with the probe assembly 3, and the motor is electrically connected with the controller, so that the controller receives the detection signal, and sends a driving instruction to the motor so as to control the motor to drive the probe assembly 3 to move.

In some embodiments, the detection component is a pressure sensor or a photoelectric sensor or a limit switch, etc.

The disclosure further provides an electronic device, including a wearable device and a base, the base is for charging the wearable device and/or performing data transmission with the wearable device, wherein the electronic device further includes: the probe structure mentioned above, and the wearable device is electrically connected with the base by means of the probe structure; and one of the wearable device and the base is a first component 1, and the other one of the wearable device and the base is a second component 2.

As shown in FIG. 1 and FIG. 3, the wearable device of the disclosure can be a ring-type device worn on a finger of a human body, and the base is a charging base of the ring-type device.

In some embodiments, the housing 10 of the first component 1 and the body 20 of the second component 2 can be made of any one or a combination of several of ABS, PC, rubber, plastic, metal or alloy materials. The conductive component 21 on the body 20 of the second component 2 is a conductive contact, and the conductive component and the needle body 32 can be made of a metal or alloy or other materials having good conductivity such as copper, iron and aluminum.

In some embodiments, in the disclosure, the housing 10 and the body 20 are made of an ABS material, and the conductive component 21 and the needle body 32 are made of a copper alloy material. In this way, not only can the structural strength and charging efficiency of the electronic device be guaranteed, but the production cost of the electronic device can also be controlled, and the production efficiency of the electronic device is improved.

As can be seen from the above descriptions, the above embodiments of the disclosure achieve the following technical effects:

The probe structure of the disclosure is disposed on the first component 1 for contacting with the conductive component 21 on the second component 2, so as to form an electrical connection between the first component 1 and the second component 2, the probe structure includes the probe assembly 3, the probe assembly 3 includes the storage position at which the probe assembly is stored in the first component 1 so as to avoid being damaged by the external force, and the contact position at which the probe assembly at least partially extends out of the first component 1 so as to contact with the conductive component 21, and the probe assembly 3 is movably disposed to move between the storage position and the contact position. In this way, when the second component 2 needs to be electrically connected with the first component 1, the needle body of the probe assembly 3 can extend out of the first component 1, so as to contact with the conductive component 21 of the second component 2; and when the second component 2 does not need to be electrically connected with the first component 1, the needle body of the probe assembly 3 can be stored back in the first component 1 and no longer protrudes out or exceeds the outer surface of the first component 1, so as to avoid a fault or failure caused by an internal collision resulting from an external acting force, thereby solving the problem of a probe assembly of a probe structure in the prior art being prone to an external acting force to damage an internal structure.

It should be noted that, terms used herein are for the purpose of describing specific embodiments, and are not intended to limit the exemplary embodiments according to the disclosure. As used herein, unless the context clearly dictates otherwise, a singular form is intended to include a plural form as well. In addition, it should also be understood that, when the terms “contain” and/or “include” are used in the present specification, they indicate the presence of features, steps, operations, devices, assemblies and/or combinations thereof.

Unless specifically stated otherwise, relative arrangements, numerical expressions and numerical values of components and steps set forth in these embodiments do not limit the scope of the disclosure. Meanwhile, it should be understood that, for the convenience of description, the dimensions of various parts shown in the drawings are not drawn according to an actual proportional relationship. Techniques, methods and devices known to those ordinary skilled in related arts cannot be discussed in detail, but where appropriate, such techniques, methods and devices should be considered as a part of the authorized specification. In all examples shown and discussed herein, any specific value should be construed as illustrative only and not as restrictive. Accordingly, other examples of the exemplary embodiments can have different values. It should be noted that similar reference signs and letters refer to similar items in the following figures, so once a certain item is defined in one figure, it does not require further discussion in subsequent figures.

In the description of the disclosure, it should be understood that orientation or position relationships indicated by orientation words such as “front, back, upper, lower, left, right”, “transverse, longitudinal, vertical, horizontal” and “top, bottom” and the like are generally orientation or position relationships shown on the basis of the drawings, and are merely for the convenience of describing the disclosure and simplifying the description, in the absence of opposite statements, these orientation words do not indicate or imply that the referred apparatuses or elements must have specific orientations or must be constructed and operated in specific orientations, and thus cannot be construed as limiting the protection scope of the disclosure; and the orientation words “inside and outside” refer to the inside and outside of the contours of the components themselves.

For the convenience of description, spatially relative terms, such as “on”, “above”, “on the upper surface of”, “over” and the like, can be used herein to describe spatial position relationships between one device or feature and other devices or features shown in the figures. It should be understood that, the spatially relative terms are intended to contain different orientations of a device in use or operation in addition to the orientations described in the figures. For example, if the device in the figures is turned over, the device, which is described as “above other devices or structures” or “over other devices or structures” would then be positioned as “below other devices or structures” or “beneath other devices or structures”. Thus, the exemplary term “above” can include both orientations of “above” and “below”. The device can also be otherwise positioned (rotated by 90 degrees or at other orientations), and the spatially relative descriptions used herein are interpreted accordingly.

In addition, it should be noted that the terms “first”, “second” and the like are used for defining components and parts, and are merely for the convenience of distinguishing the corresponding components and parts, and unless otherwise stated, the above words have no special meaning, and thus cannot be construed as limiting the protection scope of the disclosure.

The above descriptions are only preferred embodiments of the disclosure, and are not intended to limit the disclosure. For those skilled in the art, the disclosure can have various modifications and changes. Any modifications, equivalent replacements, improvements and the like, made within the spirit and principle of the disclosure, shall be included within the protection scope of the disclosure.

What is claimed is:

1. A probe structure, which is disposed on a first component (1) and is configured to contact with a conductive component (21) on a second component (2), wherein the probe structure comprises:
a probe assembly (3), comprising a storage position and a contract position, when the probe assembly is at the storage position, the probe assembly is stored in the first component (1) so as to avoid being damaged by an external force, and when the probe assembly is at the contact position, at least part of the probe assembly extends out of the first component (1) so as to contact with the conductive component (21); the probe assembly (3) is movably disposed to move between the storage position and the contact position.

2. The probe structure as claimed in claim 1, wherein the probe structure further comprises:
a driving assembly (4), which is movably disposed on the first component (1), and the driving assembly (4) is connected with the probe assembly (3), so as to drive the probe assembly (3) to move between the storage position and the contact position.

3. The probe structure as claimed in claim 2, wherein the first component (1) comprises a housing (10), and an avoidance groove is disposed on an outer surface of the housing, wherein,
when the probe assembly (3) is at the storage position, the probe assembly (3) is stored in the avoidance groove (12); or,
an accommodating cavity (11) which communicates with the avoidance groove (12) for accommodating the driving assembly (4) is disposed on the housing, and when the probe assembly (3) is at the storage position, the probe assembly (3) is stored in the accommodating cavity (11) after passing through the avoidance groove (12); or,
an accommodating cavity (11) which communicates with the avoidance groove for accommodating the driving assembly (4) is disposed on the housing, and when the probe assembly (3) is at the storage position, a part of the probe assembly (3) is stored in the avoidance groove (12), and the other part of the probe assembly (3) is stored in the accommodating cavity (11).

4. The probe structure as claimed in claim 3, wherein the probe assembly (3) comprises a rotating portion (31) and a needle body (32), the rotating portion (31) is rotatably disposed on the avoidance groove (12), one end of the needle body (32) is connected with the rotating portion (31), and the other end of the needle body (32) extends in a direction away from the rotating portion (31); the needle body retracts into the first component (1) or extends out of the first component (1) by means of the rotation of the rotating portion (31).

5. The probe structure as claimed in claim 4, wherein an insertion protrusion is disposed on one of the avoidance groove (12) and the rotating portion (31), an insertion groove is disposed on the other one of the avoidance groove (12) and the rotating portion (31); the insertion protrusion is inserted into the insertion groove and is in clearance fit with the insertion groove, and the rotating portion (31) rotates relative to the avoidance groove (12).

6. The probe structure as claimed in claim 3, wherein at least part of the driving assembly (4) is disposed on the accommodating cavity (11), and the driving assembly (4) comprises:
a first transmission member (41), rotatably disposed on the first component (1); and
a second transmission member (42), a first end of the second transmission member is slidably and rotatably connected with the first transmission member (41), and a second end of the second transmission member is hinged with the probe assembly (3); the second transmission member (42) drives the probe assembly (3) to move by means of the rotation of the first transmission member (41).

7. The probe structure as claimed in claim 6, wherein the first transmission member (41) comprises:
a driving portion (411), a first end of the driving portion (411) is disposed outside the housing (10), a second end of the driving portion (411) is disposed on the accommodating cavity (11); the second end of the driving portion (411) is rotatably connected with the housing (10), and the second end of the driving portion (411) rotates by means of driving the first end of the driving portion (411) to move; and
a transmission portion (412), the transmission portion (412) is disposed on the accommodating cavity (11), a first end of the transmission portion (412) is connected with the second end of the driving portion (411), a groove is disposed on a second end of the transmission portion (412), and the first end of the second transmission member (42) is rotatably and slidably disposed in the groove (413).

8. The probe structure as claimed in claim 7, wherein,
at least part of the driving portion (411) is a strip-shaped rod body (4111), and the center line of the strip-shaped rod body (4111) and the rotation axis of the driving portion (411) are disposed at a predetermined angle;
the transmission portion (412) comprises a first rod body (4121) and a second rod body (4122) which are connected with each other, an end of the first rod body (4121) which is away from the second rod body (4122) is connected with a second end of the strip-shaped rod body (4111), and an end of the second rod body (4122) which is away from the first rod body (4121) is connected with the second transmission member (42); and
the center lines of any two of the strip-shaped rod body (4111), the first rod body (4121) and the second rod body (4122) are disposed at a predetermined angle, so as to jointly form the first transmission member (41).

9. The probe structure as claimed in claim 7, wherein,
the driving portion (411) comprises a strip-shaped rod body (4111) and a protrusion portion (4112) which is located at a first end of the strip-shaped rod body (4111); at least part of the strip-shaped rod body (4111) is disposed on the accommodating cavity (11);
a mounting groove for accommodating the second component is disposed on the first component (1), an opening portion corresponding to the protrusion portion is disposed on a groove wall surface of the mounting groove (13), and the protrusion portion (4112) is movably disposed at the opening portion (14); and
the protrusion portion (4112) comprises an initial position and an avoidance position, when the protrusion is at the initial position, at least part of the protrusion portion protrudes out of the opening portion to be disposed on the mounting groove (13) so as to contact with the opening portion; when the protrusion portion is at the avoidance position, the protrusion portion is completely located in the opening portion (14) to avoid the second component (2), and the protrusion portion (4112) is movably disposed between the initial position and the avoidance position.

10. The probe structure as claimed in claim 9, wherein the driving assembly (4) comprises:
an elastic reset member, the elastic reset member is disposed between a side of the strip-shaped rod body (4111) which is away from the protrusion portion (4112) and the housing (10); and
the protrusion portion (4112) reaches the avoidance position from the initial position under the propulsion of the second component (2), so as to compress the elastic reset member; or, the protrusion portion (4112) returns from the avoidance position to the initial position under the action of an elastic force of the elastic reset member.

11. The probe structure as claimed in claim 7, wherein the driving portion (411) comprises a strip-shaped rod body (4111) and a rotary connecting portion (4113) which is located at a second end of the strip-shaped rod body (4111), a shaft body is disposed on one of the rotary connecting portion (4113) and the housing (10), a shaft hole is disposed on the other one of the rotary connecting portion (4113) and the housing (10); the shaft body is inserted into the shaft hole, and the driving portion (411) rotates relative to the housing (10).

12. The probe structure as claimed in claim 7, wherein,
the probe assembly (3) comprises a rotating portion (31) and a needle body, the rotating portion is rotatably disposed in the avoidance groove (12), and the needle body (32) is connected with the rotating portion (31) so as to rotate along with the rotating portion (31); and
the second transmission member (42) comprises a connecting rod (421), a first connecting shaft (422) and a second connecting shaft (423), the first connecting shaft and the second connecting shaft are respectively disposed at two ends of the connecting rod (421), the center lines of the first connecting shaft (422) and the second connecting shaft (423) are parallel to each other and are perpendicular to the center line of the connecting rod (421), the first connecting shaft (422) is configured to connect with the first transmission member (41), and the second connecting shaft (423) is configured to hinge with the rotating portion (31), so as to drive the rotating portion (31) to rotate.

13. The probe structure as claimed in claim 8, wherein,
the probe assembly (3) comprises a rotating portion (31) and a needle body, the rotating portion is rotatably disposed in the avoidance groove (12), and the needle body (32) is connected with the rotating portion (31) so as to rotate along with the rotating portion (31); and
the second transmission member (42) comprises a connecting rod (421), a first connecting shaft (422) and a second connecting shaft (423), the first connecting shaft and the second connecting shaft are respectively disposed at two ends of the connecting rod (421), the center lines of the first connecting shaft (422) and the second connecting shaft (423) are parallel to each other and are perpendicular to the center line of the connecting rod (421), the first connecting shaft (422) is configured to connect with the first transmission member (41), and the second connecting shaft (423) is configured to hinge with the rotating portion (31), so as to drive the rotating portion (31) to rotate.

14. The probe structure as claimed in claim 9, wherein,
the probe assembly (3) comprises a rotating portion (31) and a needle body, the rotating portion is rotatably disposed in the avoidance groove (12), and the needle body (32) is connected with the rotating portion (31) so as to rotate along with the rotating portion (31); and
the second transmission member (42) comprises a connecting rod (421), a first connecting shaft (422) and a second connecting shaft (423), the first connecting shaft and the second connecting shaft are respectively disposed at two ends of the connecting rod (421), the center lines of the first connecting shaft (422) and the second connecting shaft (423) are parallel to each other and are perpendicular to the center line of the connecting rod (421), the first connecting shaft (422) is configured to connect with the first transmission member (41), and the second connecting shaft (423) is configured to hinge with the rotating portion (31), so as to drive the rotating portion (31) to rotate.

15. The probe structure as claimed in claim 10, wherein,
the probe assembly (3) comprises a rotating portion (31) and a needle body, the rotating portion is rotatably disposed in the avoidance groove (12), and the needle body (32) connected with the rotating portion (31) so as to rotate along with the rotating portion (31); and
the second transmission member (42) comprises a connecting rod (421), a first connecting shaft (422) and a second connecting shaft (423), the first connecting shaft and the second connecting shaft are respectively disposed at two ends of the connecting rod (421), the center lines of the first connecting shaft (422) and the second connecting shaft (423) are parallel to each other and are perpendicular to the center line of the connecting rod (421), the first connecting shaft (422) is configured to connect with the first transmission member (41), and the second connecting shaft (423) is configured to hinge with the rotating portion (31), so as to drive the rotating portion (31) to rotate.

16. The probe structure as claimed in claim 11, wherein,
the probe assembly (3) comprises a rotating portion (31) and a needle body, the rotating portion is rotatably disposed in the avoidance groove (12), and the needle body (32) connected with the rotating portion (31) so as to rotate along with the rotating portion (31); and
the second transmission member (42) comprises a connecting rod (421), a first connecting shaft (422) and a second connecting shaft (423), the first connecting shaft and the second connecting shaft are respectively disposed at two ends of the connecting rod (421), the center lines of the first connecting shaft (422) and the second connecting shaft (423) are parallel to each other and are perpendicular to the center line of the connecting rod (421), the first connecting shaft (422) is configured to connect with the first transmission member (41), and the second connecting shaft (423) is configured to hinge with the rotating portion (31), so as to drive the rotating portion (31) to rotate.

17. The probe structure as claimed in claim 3, wherein the probe assembly (3) comprises a needle rod and a needle cylinder, the needle cylinder is disposed on the accommodating cavity (11), and at least part of the needle rod is telescopically disposed in the needle cylinder, so as to extend out of the needle cylinder to contact with the conductive component (21) or retract into the needle cylinder to avoid being damaged.

18. The probe structure as claimed in claim 17, wherein the driving assembly (4) comprises:
an armature, disposed on an end of the needle rod close to the bottom of the needle cylinder and is fixedly connected with the needle rod;
a coil and iron core assembly, disposed on the bottom of the needle cylinder; and
an elastic connecting member, disposed between the armature and the coil and iron core assembly, so as to connect the armature with the coil and iron core assembly.

19. The probe structure as claimed in claim 2, wherein the driving assembly (4) comprises:
a detection component, be configured to detect whether the second component (2) reaches a predetermined position on the first component (1), and transmitting a detection signal to a controller; and
a motor, an output shaft of the motor is connected with the probe assembly (3), and the motor is electrically connected with the controller; the controller receives the detection signal and sends a driving instruction to the motor, so as to control the motor to drive the probe assembly (3) to move.

20. An electronic device, comprising a wearable device and a base, the base is configured to charge the wearable device or perform data transmission with the wearable device or charge the wearable device and perform data transmission with the wearable device, wherein the electronic device further comprises:
a probe structure as claimed in claim 1, the wearable device is electrically connected with the base by means of the probe structure; and one of the wearable device and the base is a first component (1), and the other one of the wearable device and the base is a second component (2).
